(19) United States
(12) Patent Application Publication
(10) Pub. No.: US 2025/0255022 A1
(43) Pub. Date: Aug. 7, 2025

(54) IMAGE SENSOR

(71) Applicant: Samsung Electronics Co., Ltd., Suwon-si (KR)

(72) Inventors: Mingyu Bae, Suwon si (KR); Hye Yeon Park, Suwon-si (KR); Boseong Kim, Suwon-si (KR); Sangin Bae, Suwon-si (KR); Hyunseok Song, Suwon-si (KR)

(21) Appl. No.: 19/021,744

(22) Filed: Jan. 15, 2025

(30) Foreign Application Priority Data
Feb. 7, 2024 (KR) 10-2024-0019165

(51) Int. Cl. H10F 39/00

(52) U.S. Cl. CPC H10F 39/8063; H10F 39/802

(57) ABSTRACT

An image sensor includes a pixel array including pixels and a microlens array arranged above the pixel array, each of the pixels includes at least two photoelectric transformation elements. The microlens array includes microlenses respectively corresponding to the pixels in the pixel array, and as a distance from a center of the pixel array to the pixels included in the pixel array increases, a horizontal cross-sectional width of a microlens corresponding to the pixels increases.

### CROSS-REFERENCE TO RELATED APPLICATION

This application is based on and claims priority under 35 U.S.C. § 119 to Korean Patent Application No. 10-2024-0019165, filed on Feb. 7, 2024, in the Korean Intellectual Property Office, the disclosure of which is incorporated by reference herein in its entirety.

### BACKGROUND

Aspects of the inventive concept relate to an image sensor, and more particularly, to a structure of a microlens for improving auto-focusing of an image sensor.

Image sensors that capture images and convert them into electrical signals are used not only in electronic devices for general consumers, such as digital cameras, mobile phone cameras, and portable camcorders, but also in cameras mounted on vehicles, security systems, and robots. An image sensor may include a pixel array, and each pixel included in the pixel array may include a photodiode. Image sensors are required to perform an autofocusing (AF) function to accurately capture moving images in a short period of time.

### SUMMARY

Aspects of the inventive concept provide microlenses configured to improve an autofocusing (AF) function based on an arrangement of microlenses that increase in a cross-sectional width as the microlenses get farther from the center of a pixel array.

According to an aspect of the inventive concept, there is provided an image sensor including a pixel array including a plurality of pixels, and a microlens array arranged above the pixel array, wherein each of the plurality of pixels includes at least two photoelectric transformation elements, the microlens array includes a plurality of microlenses respectively corresponding to the plurality of pixels in the pixel array, and as a distance from a center of the pixel array to the pixels included in the pixel array increases, a horizontal cross-sectional width of a microlens corresponding to the pixels increases.

According to another aspect of the inventive concept, there is provided an image sensor including a pixel array including a plurality of pixels each including at least two photoelectric transformation elements, and a microlens array corresponding to each of the plurality of pixels included in the pixel array, wherein the microlens array includes a first area including a plurality of first microlenses and a second area including a plurality of second microlenses, and a distance from a center of the microlens array to the plurality of first microlenses in the first area is less than a distance from the center of the microlens array to the plurality of second microlenses in the second area, and a cross-sectional width of each of the plurality of second microlenses is greater than a cross-sectional width of each of the plurality of the first microlenses.

According to another aspect of the inventive concept, there is provided an image sensor including a pixel array including a first pixel and a second pixel, and a microlens array including a first microlens, which corresponds to the first pixel and is arranged above the first pixel, and a second microlens, which corresponds to the second pixel and is arranged above the second pixel, a distance from a center of the pixel array to the second pixel is greater than a distance from the center of the pixel array to the first pixel, a horizontal cross-sectional shape of the first microlens is different from a horizontal cross-sectional shape of the second microlens, and a maximum diagonal length of the horizontal cross-section of the second microlens is greater than a maximum diagonal length of the horizontal cross-section of the first microlens.

### BRIEF DESCRIPTION OF THE DRAWINGS

Embodiments of the inventive concept will be more clearly understood from the following detailed description taken in conjunction with the accompanying drawings in which:

FIG. 1 illustrates a structure of a digital imaging device, according to an embodiment;

FIG. 2 is a block diagram of an image sensor according to an embodiment;

FIG. 3 illustrates a pixel array according to an embodiment;

FIG. 4 three-dimensionally illustrates at least a portion of an image sensor, according to an embodiment;

FIG. 5A illustrates a structure of a microlens according to an embodiment;

FIG. 5B is a cross-sectional view of the image sensor of FIG. 5A, taken along a line I-I′;

FIG. 5C is a diagram illustrating pixels including photodiodes, according to an embodiment;

FIG. 6A illustrates that cross-sectional shapes of microlenses are different, according to an embodiment;

FIG. 6B illustrates structures of microlenses with different curvatures, according to an embodiment;

FIG. 7 illustrates a shape of a microlens according to an embodiment;

FIG. 8A illustrates microlenses each including a first lens area and a second lens area, according to an embodiment;

FIG. 8B illustrates microlenses each including a first lens area and a second lens area, according to an embodiment;

FIG. 9A illustrates a structure in which cross-sectional shapes of a first lens area and a second lens area of a microlens are different, according to an embodiment;

FIG. 9B illustrates a structure in which cross-sectional shapes of a first lens area and a second lens area of a microlens are different, according to an embodiment;

FIG. 10 illustrates a structure in which a cross-sectional shape of a second lens area varies depending on the distance from a center of a pixel array, according to an embodiment;

FIG. 11A illustrates slits of a microlens according to an embodiment;

FIG. 11B illustrates slits of a microlens according to an embodiment;

FIG. 12 illustrates a structure in which the microlenses of FIG. 5A are shifted;

FIG. 13 illustrates a microlens array according to an embodiment; and

FIG. 14 is a block diagram of an electronic device according to an embodiment.

### DETAILED DESCRIPTION OF THE EMBODIMENTS

Hereinafter, one or more embodiments are described in detail with reference to the attached drawings. Like reference numerals in the drawings denote like elements, and repeated descriptions thereof will be omitted.

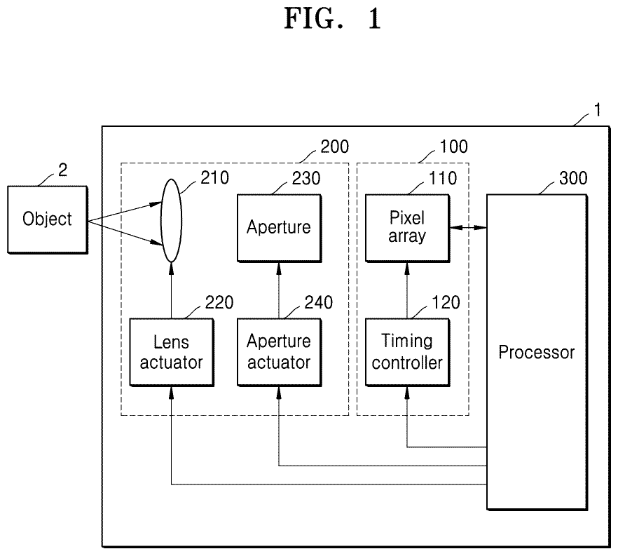

FIG. 1 illustrates a structure of a digital imaging device 1, according to an embodiment. The digital imaging device 1 may perform an autofocus (AF) function.

The digital imaging device 1 according to an embodiment may include an imaging unit 200, an image sensor 100, and a processor 300. The digital imaging device 1 may have a focus-detecting function. The digital imaging device 1 may be an electronic device having an image or light sensing function. For example, the electronic device may be any one of a camera, a smartphone, a wearable device, an Internet of Things (IOT) device, a tablet personal computer (PC), a personal digital assistant (PDA), a portable multimedia player (PMP), and a navigation device. For example, the electronic device may be a device mounted as a component on vehicles, furniture, manufacturing facilities, doors, or various measurement devices.

Processes of the digital imaging device 1 may be controlled by the processor 300. The processor 300 may transmit control signals and the like to a lens actuator 220, an aperture actuator 240, a timing controller 120 for the operation of each component.

The imaging unit 200 may be a component configured to receive light and may include a lens 210, the lens actuator 210, an aperture 230, and the aperture actuator 240. The lens 210 may include a plurality of lenses.

The lens actuator 220 may exchange information regarding focus detection with the processor 300 and may adjust the position of the lens 210 according to a control signal from the processor 300. The lens actuator 220 may move the lens 210 in a direction in which a distance from an object 2 increases or decreases. Thus, the distance between the lens 210 and the object 2 may be adjusted. The object 2 may be in focus or blurred depending on the position of the lens 210.

For example, when the lens 210 is relatively close to the object 2, the lens 210 may be out of the in-focus position for focusing on the object 2, and there may be a phase difference between images captured by the image sensor 100. The lens actuator 220 may move the lens 210 in the direction away from the object 2, based on the control signal from the processor 300.

Alternatively, when the distance between the lens 210 and the object 2 is relatively great, the lens 210 may be out of the focal position, and a phase difference may occur between the images focused on the image sensor 100. The lens actuator 220 may move the lens 210 in the direction in which the distance from the object 2 decreases, based on the control signal from the processor 300.

The image sensor 100 may convert incident light into an image signal. The image sensor 100 may include a pixel array 110 and a timing controller 120. An optical signal passing through the lens 210 and the aperture 230 may reach a light-receiving surface of the pixel array 110 and form an image of a subject.

The pixel array 110 may be a complementary metal oxide semiconductor image sensor (CIS) that converts an optical signal into an electrical signal. The sensitivity and other parameters of the pixel array 110 may be adjusted by the timing controller 120. The pixel array 110 may include a plurality of pixels that convert an optical signal into an electrical signal. Each pixel may generate a pixel signal according to the intensity of the detected light. The pixel array 110 may include pixels for performing an AF function or a distance detecting function. For example, the pixels included in the pixel array 110 may be pixels for performing the AF function.

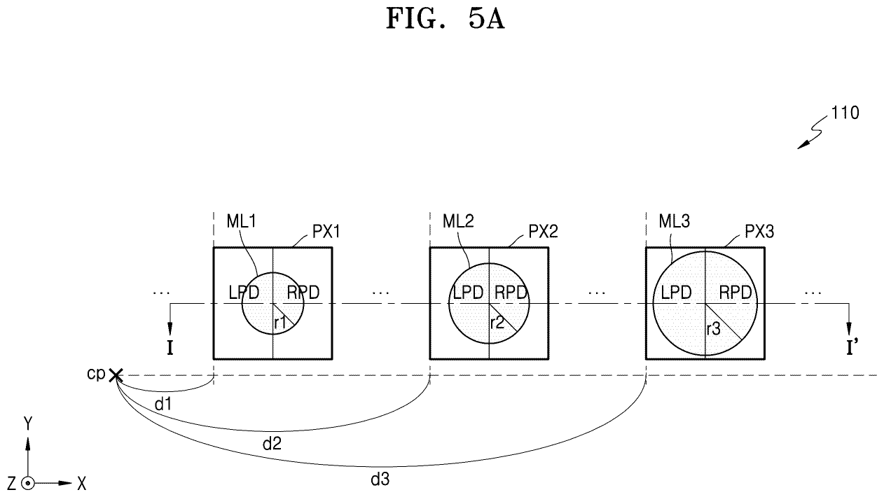

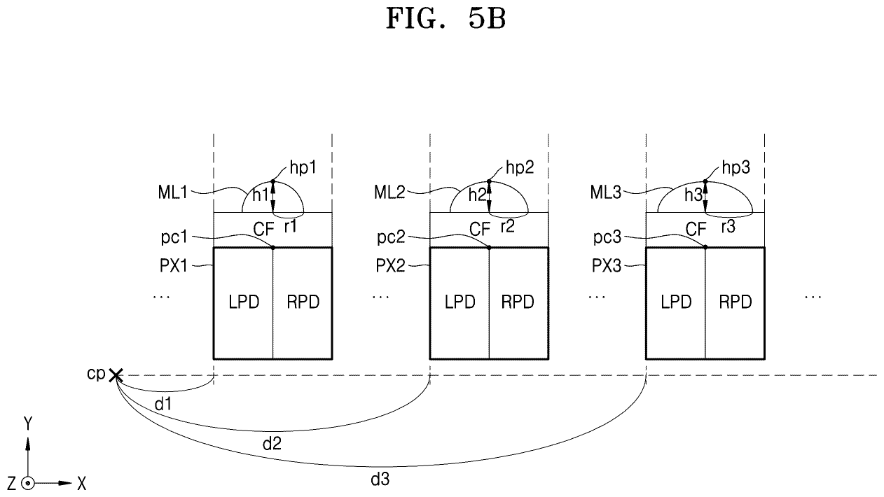

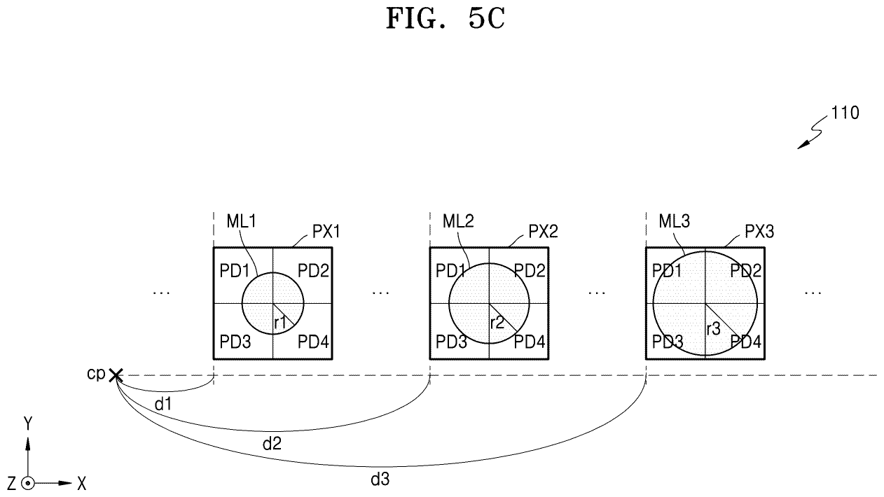

The image sensor 100 may include a microlens array arranged above the pixel array 110. The microlens array may include a plurality of microlenses respectively corresponding to the pixels included in the pixel array 110. The widths of the horizontal cross-sections of the microlenses corresponding to the pixels may increase as the distance from the center of the pixel array 110 to the pixels increases. The microlens is described in detail starting from FIG. 5A.

The image sensor 100 may provide image information to the processor 300, and the processor 300 may then use the image information to perform phase difference calculations. The processor 300 may process data that is output from the image sensor 100. The processor 300 may calculate the focal position, the focal direction, or the distance between the object 2 and the image sensor 100, according to the results of the phase difference calculations. The processor 300 may output a control signal to the lens actuator 220 to adjust the position of the lens 210, based on the results of the phase difference calculations.

The processor 300 may reduce noise from an input signal and perform image signal processing for enhancements such as gamma correction, color filter array interpolation, color matrix, color correction, or color enhancement. In addition, the processor 300 may generate image files by compressing image data produced through image signal processing for image enhancement or may restore image data from the image files.

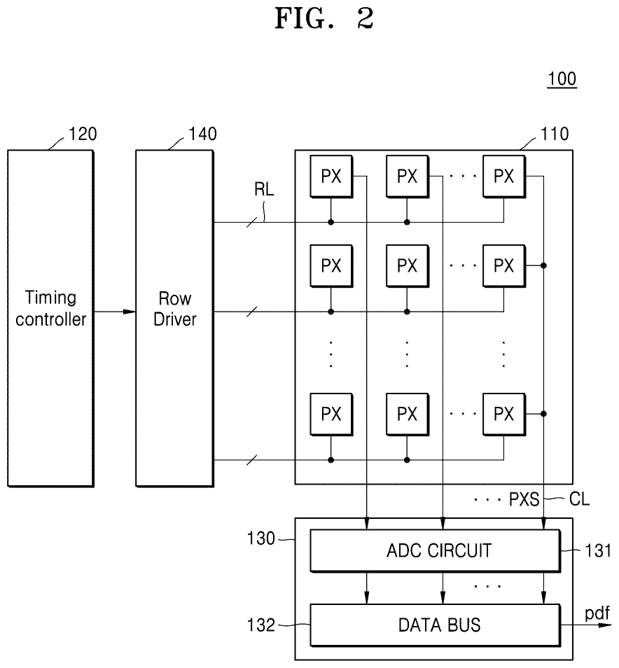

FIG. 2 is a block diagram of an image sensor according to an embodiment.

The image sensor 100 may convert an optical signal of an object, which is incident through an optical lens, into image data. The image sensor 100 may be, for example, a charge coupled device (CCD) image sensor or a complementary metal oxide semiconductor (CMOS) image sensor.

Referring to FIG. 2, the image sensor 100 may include the pixel array 110, the timing controller 120, a readout circuit 130, and a row driver 140. The readout circuit 130 may include an analog-digital conversion circuit 131 (hereinafter, referred to as an ADC circuit) and a data bus 132.

The pixel array 110 includes a plurality of row lines RL, a plurality of column lines CL, and a plurality of pixels PX that connect the row lines RL and the column lines CL and are arranged in a matrix form. In an embodiment, the pixels PX may each be an active pixel sensor (APS). The pixel array 110 may include the pixels PX that detect light in different wavelengths. The arrangement of the pixels PX may vary.

Each pixel PX may include at least one photoelectric transformation element. The pixel PX may detect light using the photoelectric transformation element and may output an image signal, which is an electrical signal, according to the detected light. For example, the photoelectric transformation element may be a light-sensing device including an organic material or an inorganic material, such as an inorganic photodiode, an organic photodiode, a perovskite photodiode, a phototransistor, a photo gate, or a pinned photodiode. In an embodiment, each pixel PX may include a plurality of photoelectric transformation elements. For example, each pixel PX may include two or four photoelectric transformation elements, but one or more embodiments are not limited thereto.

Microlenses (e.g., the microlenses ML of FIG. 5A) for collecting light may be arranged above each pixel PX or each pixel group including adjacent pixels PX. For example, a plurality of microlenses may be arranged above each pixel PX, the microlenses respectively corresponding to the pixels PX. Each pixel PX may detect light in a specific spectral region from the light received through the microlens arranged above each pixel PX.

The microlenses may be configured such that their cross-sectional widths increase as the distance from the center of the pixel array 110 to the pixels PX increase. For example, the pixel array 110 may include a first pixel and a second pixel, and the distance from the center of the pixel array 110 to the second pixel may be greater than the distance from the center of the pixel array 110 to the first pixel. That is, the second pixel may be positioned closer to the edge of the pixel array 110 than the first pixel. The cross-sectional width of a second microlens corresponding to the second pixel may be greater than the cross-sectional width of a first microlens corresponding to the first pixel. Because the cross-sectional widths of the microlenses increase towards the edges of the pixel array 110, the AF function may be enhanced, which is described below with reference to FIG. 5A.

The pixel array 110 may include at least one AF pixel. The AF pixel refers to a pixel having a circuit or a physical structure to automatically adjust the focus. The microlenses may be arranged above the AF pixels. For example, all of the pixels PX included in the pixel array 110 may be AF pixels, and a microlens may be arranged above each AF pixel.

A color filter for transmitting light in a specific spectral region may be arranged above each pixel PX, and depending on the color filter arranged above each pixel PX, a color sensed by the pixel corresponding to the color filter may be determined. However, one or more embodiments are not limited thereto, and the pixel array 110 may include pixels that convert light in spectral regions, other than red, green, and blue, into electrical signals.

In some embodiments, the pixels PX may have a multi-layer structure. The pixel PX having the multi-layer structure may include a plurality of stacked photoelectric transformation elements that convert light in different spectral regions into electrical signals, and electrical signals corresponding to different colors may be generated from the photoelectric transformation elements. In other words, electrical signals corresponding to multiple colors may be output from one pixel PX.

The row driver 140 may drive the pixel array 110 in units of rows. The row driver 140 may decode a row control signal (for example, an address signal) received from the timing controller 120 and select at least any one of the row lines forming the pixel array 110 in response to the decoded row control signal. For example, the row driver 140 may generate a selection signal configured to select one of the rows. The pixel array 110 outputs a pixel signal PXS from the row selected based on the selection signal provided from the row driver 140.

The row driver 140 may transmit control signals for outputting the pixel signal PXS to the pixel array 110, and in response to the control signals, the pixel PX may operate and output the pixel signal PXS. For example, the row driver 140 may generate the control signals configured to control the pixel PX to output the pixel signal PXS during a read-out period and may provide the generated control signals to the pixel array 110.

The readout circuit 130 may read out the pixel signal PXS from the pixels PX in the row selected by the row driver 140 from among the pixels PX. In this case, the pixel signal PXS may include a reset signal or an image signal (or a sensing signal). The readout circuit 130 may convert reset signals and image signals, which are transmitted from the pixel array 110 through the column lines CL, into digital signals based on the ramp signals from the ramp signal generator, thus generating and outputting pixel values pdf corresponding to the pixels PX in units of rows.

The ADC circuit 131 may include a plurality of ADCs respectively corresponding to the column lines CL, and each ADC may compare each of a reset signal and an image signal, which are received through its corresponding column line CL, with a ramp signal and generate a pixel value pdf based on a comparison result. For example, the ADC may remove the reset signal from the image signal and generate a pixel value pdf that indicates the light amount sensed by the pixel PX. The pixel values pdf generated by the ADC circuit 131 may be output through the data bus 132.

The ADC circuit 131 may include a plurality of correlated double sampling (CDS) circuits (not shown) and a plurality of counter circuits (not shown). The ADC circuit 131 may convert the pixel signal PXS, which is input from the pixel array 110, into the pixel value pdf that is a digital signal. Each pixel signal PXS received through each column line CL is converted into the pixel value pdf by the CDS circuit and the counter circuit, the pixel value pdf being the digital signal.

The CDS circuit may compare the pixel signal PXS, which is received through the column line CL, with the ramp signal and may output the comparison result. When the level of the ramp signal is the same as the level of the pixel signal PXS, the CDS circuit may output a comparison signal transitioning from a first level (e.g., logic high) to a second level (e.g., logic low). The point in time when the level of the comparison result transitions may be determined according to the level of the pixel signal PXS.

The CDS circuit may sample and hold the pixel signal PXS provided from the pixel PX according to the CDS method and may doubly sample the level of specific noise (e.g., the reset signal) and the level of the image signal, thus generating the comparison signal based on the level corresponding to the difference between the two levels.

The data bus 132 may temporarily store the pixel values pdf, which are output from the ADC circuit 131, and may output the same. The data bus 132 may include a plurality of column memories and a column decoder. The pixel values pdf stored in the column memories may be output to a signal processor inside the image sensor 100 or an image signal processor outside the image sensor 100, under the control of the column decoder.

According to an embodiment, the image sensor 100 may include a signal processor. The signal processor may perform, on the pixel values pdf, noise reduction, gain adjustment, waveform shaping, interpolation, white balancing, gamma correction, edge enhancement, binning, and the like. During AF operations, the signal processor may perform signal processing based on phase signals that are output from the AF pixels and may output processed data to the processor (e.g., the processor 300 of FIG. 1), enabling the processor to calculate phase differences for the AF operations. In an embodiment, the signal processor may be included in a processor outside the image sensor 100 (e.g., the processor 300 of FIG. 1).

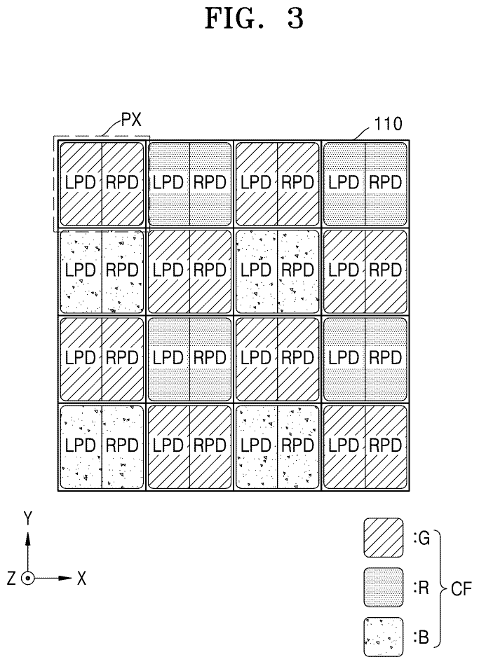

FIG. 3 illustrates a pixel array according to an embodiment. FIG. 3 illustrates an example of the pixel array corresponding to color filters. Because the pixel array 110 of FIG. 3 corresponds to the pixel array 110 of FIG. 2, the repeated descriptions thereof are omitted.

Referring to FIG. 3, the pixel array 110 may include pixels PX. Each pixel PX may include a plurality of photodiodes. For example, each pixel PX may include a first photodiode LPD and a second photodiode RPD. For example, a pixel signal (e.g., the pixel signal PXS of FIG. 2) generated from each of the first photodiode LPD and the second photodiode RPD may be output to the readout circuit (e.g., the readout circuit 130 of FIG. 2). FIG. 3 illustrates that each pixel PX includes two photodiodes, but one or more embodiments are not limited thereto. The number of photodiodes included in each pixel PX may be four or vary.

The pixel array 110 may further include a color filter array CF to make the pixels PX sense various colors. For example, the color filter array CF may be arranged above the pixel array 110 in the Z-axis direction. The color filter array CF may include color filters configured to sense green G, red R, and blue B.

FIG. 3 illustrates a Bayer pattern. One unit pattern may include four quadrant regions, and the first quadrant to the fourth quadrant may be green G, blue B, red R, and green G, respectively. Such a unit pattern is two-dimensionally arrayed in a first direction (an X direction) and a second direction (a Y direction).

In a unit pattern formed as a 2×2 array, a green filter G and another green filter G are arranged along a diagonal direction, while a blue filter B and a red filter R are arranged along the opposite diagonal direction. The first row, in which first green filters G and blue filters B are alternated in the first direction, and the second row, in which red filters B and green filters G are alternated in the second direction, are repeated in the second direction.

The arrangement of the color filter array CF may vary besides the Bayer pattern. For example, a CYGM arrangement may also be available, where a magenta filter, a cyan filter, a yellow filter, and a green filter G form one unit pattern.

Moreover, an RGBW arrangement may also be possible, where a green filter G, a red filter R, a blue filter B, and a white filter W form one unit pattern. Also, the unit pattern may be a 3×2 array unit pattern. Pixels in the color filter array CF may be arranged in various forms, depending on the uses and characteristics of the image sensor (e.g., the image sensor 100 of FIG. 2). The image sensor may be applied to not only the Bayer pattern but also other types of color filter arrangements.

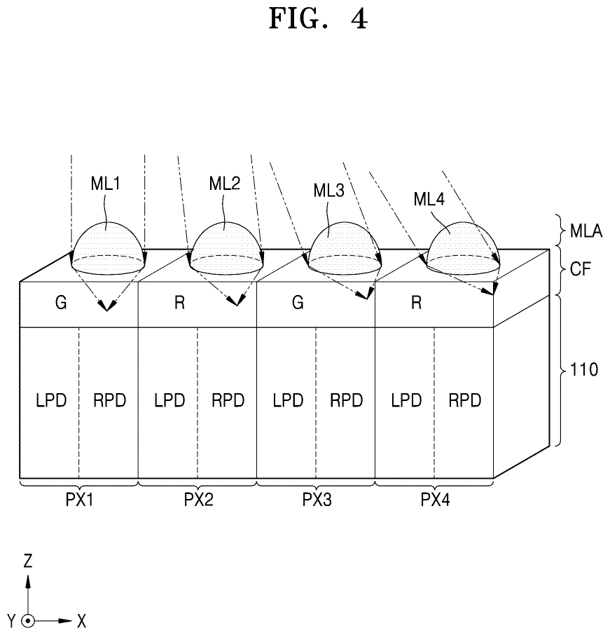

FIG. 4 three-dimensionally illustrates at least a portion of an image sensor, according to an embodiment. FIG. 4 illustrates that microlenses ML of a microlens array MLA have the same size and shape, according to the comparative example.

Referring to FIG. 4, a pixel array 110 may include a first pixel PX1, a second pixel PX2, a third pixel PX3, and a fourth pixel PX4. The first pixel PX1 may refer to a pixel that is relatively close to the center (e.g., the center cp of FIG. 5a) of the pixel array 110. The center cp of the pixel array 110 may refer to the midpoint of the pixel array 110. The distance from the center cp to the second pixel PX2 may be greater than that to the first pixel PX1. That is, the second pixel PX2 may be farther from the center cp of the pixel array 110 than the first pixel PX1. The distance from the center cp to the third pixel PX3 may be greater than that to the second pixel PX2. That is, the third pixel PX3 may be farther from the center cp of the pixel array 110 than the second pixel PX2. The distance from the center cp to the fourth pixel PX4 may be greater than that to the third pixel PX3. That is, the fourth pixel PX4 may be farther from the center cp of the pixel array 110 than the third pixel PX3.

The color filter array CF may be arranged above the pixel array 110. For example, the green filter G may be arranged in the first pixel PX1, the red filter R may be arranged in the second pixel PX2, the green filter G may be arranged in the third pixel PX3, and the red filter R may be arranged in the fourth pixel PX4. However, one or more embodiments are not limited thereto.

In the pixel array 110, the direction from the first pixel PX1 towards the second pixel PX2 may be the first direction, and the direction towards the color filter array CF may be the third direction. For example, the first direction may be the X-axis direction, and the third direction may be the Z-axis direction. The first direction may be perpendicular to the third direction. In the third direction, the color filter array CF may be arranged above the pixel array 110.

The microlens array MLA may be arranged above the pixel array 110 in the third direction. The microlens array MLA may include microlenses ML1 to ML4 respectively corresponding to the pixels included in the pixel array 110. The microlens array MLA may include a first microlens ML1 corresponding to the first pixel PX1, a second microlens ML2 corresponding to the second pixel PX2, a third microlens ML3 corresponding to the third pixel PX3, and a fourth microlens ML4 corresponding to the fourth pixel PX4.

In the comparative example, the microlenses ML of the microlens array MLA may have the same shape. For example, the horizontal cross-sections of the microlenses ML may have the same width. The horizontal cross-section of the microlens ML may be taken along the first direction and may refer to a cross-section in which the microlens ML contacts the color filter.

When the horizontal cross-sectional widths of the first microlens ML1 to the fourth microlens ML4 are the same, light, which is incident through the first microlens ML1 corresponding to the first pixel PX1 that is relatively close to the center cp, may be concentrated on a light-sensing region of the first pixel PX1. The light incident through the first microlens ML1 may be concentrated at the center of the first photodiode LPD and the second photodiode RPD of the first pixel PX1.

On the contrary, light, which is incident through the fourth microlens ML4 corresponding to the fourth pixel PX4 that is relatively farther from the center cp, may be focused above the light-sensing region of the fourth pixel PX4. Because the light entering through the fourth microlens ML4 may not be focused on the first photodiode LPD and the second photodiode RPD of the fourth pixel PX4 and may not also be concentrated at the center of the fourth pixel PX4, the AF separation ratio may deteriorate.

Therefore, to increase the AF separation ratio and improve the AF function, it is required to increase the focal length of light that is incident through the microlens corresponding to a pixel that is distant from the center cp. In the image sensor according to an embodiment, as the distance from the center cp to the pixel PX increases, the horizontal cross-sectional width of the microlens ML corresponding to the pixel PX may increase. Hereinafter, the configuration, in which the cross-sectional width of the microlens ML increases away from the center cp, is described.

FIG. 5A illustrates a structure of a microlens according to an embodiment. FIG. 5A illustrates horizontal cross-sections of pixels PX and microlenses ML respectively corresponding to the pixels PX. The descriptions that are the same as those provided above are omitted.

Referring to FIG. 5A, a pixel array 110 may include a first pixel PX1, a second pixel PX2, and a third pixel PX3. The first pixel PX1, the second pixel PX2, and the third pixel PX3 may each include a first photodiode LPD and a second photodiode RPD. In the pixel PX, the first photodiode LPD and the second photodiode RPD may be arranged adjacent to each other in the X-axis direction.

The first pixel PX1 may be a pixel PX that is relatively close to the center cp of the pixel array 110. For example, the distance from the center cp to the first pixel PX1 in the X-axis direction may be a first distance d1. The second pixel PX2 may be positioned in the pixel array 110 such that the distance from the center cp of the pixel array 110 to the second pixel PX2 is greater than that from the center cp to the first pixel PX1. For example, a second distance d2 from the center cp to the second pixel PX2 in the X-axis direction may be greater than the first distance d1. The third pixel PX3 may be positioned in the pixel array 110 such that the distance from the center cp of the pixel array 110 to the third pixel PX3 is greater than that from the center cp of the pixel array 110 to the second pixel PX2. For example, a third distance d3 from the center cp to the third pixel PX3 in the X-axis direction may be greater than the second distance d2.

The microlens ML may be arranged above each pixel PX. The first microlens ML1 may be arranged above the first pixel PX1. The first microlens ML1 may correspond to the first pixel PX1. The second microlens ML2 may be arranged above the second pixel PX2. The second microlens ML2 may correspond to the second pixel PX2. The third microlens ML3 may be arranged above the third pixel PX3. The third microlens ML3 may correspond to the third pixel PX3.

As the distance from the center cp of the pixel array 110 to the pixel PX increases, the horizontal cross-sectional width of the microlens ML corresponding to the pixel PX may increase. In other words, the farther a microlens ML is from the center cp, the greater the horizontal cross-sectional width of the microlens ML may become. The farther the microlens ML is from the center cp, the greater the width of the microlens ML corresponding to the pixel may become relative to the width of its corresponding pixel. For example, the horizontal cross-sectional width of the second microlens ML2 may be greater than the horizontal cross-sectional width of the first microlens ML1. The horizontal cross-section of the third microlens ML3 may have a greater width than the horizontal cross-sectional width of the second microlens ML2. The third pixel PX3 may be relatively far from the center cp, and the horizontal cross-sectional width of the third microlens ML3 may be relatively great.

As the distance from the center cp of the pixel array 110 to the pixel PX increases, the maximum diagonal length of the horizontal cross-section of the microlens ML corresponding to the pixel PX may be great. For example, the maximum diagonal length of the horizontal cross-section of the second microlens ML2 may be greater than that of the horizontal cross-section of the first microlens ML1. The maximum diagonal length of the horizontal cross-section of the third microlens ML3 may be greater than that of the horizontal cross-section of the second microlens ML2. The maximum diagonal length of the horizontal cross-section of the first microlens ML1 may be 2×r1, the maximum diagonal length of the horizontal cross-section of the second microlens ML2 may be 2×r2, and the maximum diagonal length of the horizontal cross-section of the third microlens ML3 may be 2×r3. 2×r3 may be greater than 2×r2, and 2×r2 may be greater than 2×r1.

In an embodiment, the microlenses ML respectively corresponding to the pixels PX may have the same shape, and as a microlens ML corresponds to a pixel that is far from the center cp, the maximum diameter of the horizontal cross-section of that microlens ML may increase. The description that the microlenses ML respectively corresponding to the pixels PX have the same shape may suggest that the forms and horizontal cross-sectional shapes of the microlenses ML are identical.

The horizontal cross-section of the microlens ML may be taken along the first direction and may refer to a cross-section in which the microlens ML contacts the color filter. As described above with reference to FIG. 4, the horizontal cross-section of the microlens ML may include the cross-section of the microlens ML contacting the color filter and the shape of the mask layout used to form the microlens ML. It may be understood by one of ordinary skill in the art that, when the microlens ML is shaped according to a mask layout, the cross-sectional shape of the microlens ML contacting the color filter may differ from the mask layout shape because of the condensation of lens materials during the formation of the microlens ML.

For example, the horizontal cross-sections of the first microlens ML1, the second microlens ML2, and the third microlens ML3 may be circular. However, one or more embodiments are not limited thereto. The horizontal cross-sections of the first microlens ML1, the second microlens ML2, and the third microlens ML3 may have various shapes including a quadrangular shape and a quadrangular shape with rounded edges.

As the distance from the center cp of the pixel array 110 to the pixel PX increases, the maximum diameter of the horizontal cross-section of the microlens ML corresponding to that pixel PX may increase. The maximum half-diameter of the horizontal cross-section of the first microlens ML1 may be the first half-diameter r1, the maximum half-diameter of the horizontal cross-section of the second microlens ML2 may be the second half-diameter r2, and the maximum half-diameter of the horizontal cross-section of the third microlens ML3 may be the third half-diameter r3. The third half-diameter r3 may be greater than the second half-diameter r2, and the second half-diameter r2 may be greater than the first half-diameter r1.

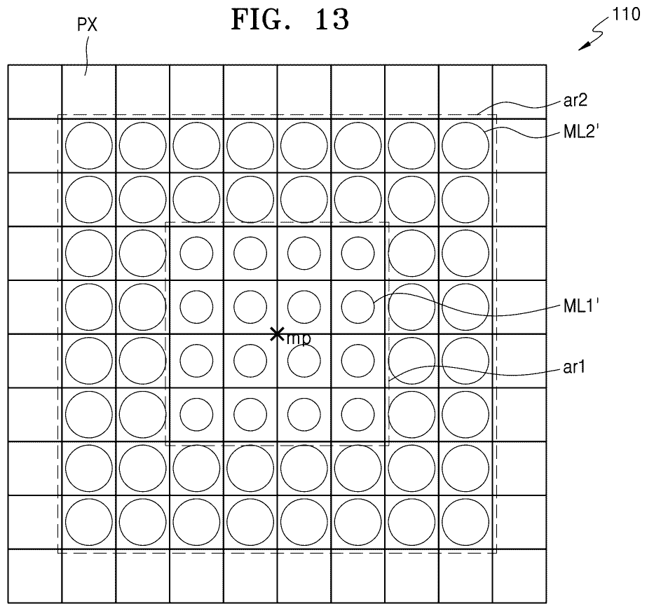

FIG. 5A illustrates the first pixel PX1, the second pixel PX2, and the third pixel PX3, but it is only for convenience of explanation. The pixel array 110 may include a greater number of pixels PX. For example, along the first direction, additional pixels PX may be included between the first pixel PX1 and the second pixel PX2, between the second pixel PX2 and the third pixel PX3, and after the third pixel PX3. The horizontal cross-sectional widths of the microlenses ML respectively corresponding to the pixels PX may gradually increase as the microlenses ML become farther from the center cp. For example, the microlenses ML respectively corresponding to the pixels PX between the first pixel PX1 and the second pixel PX2 may have a maximum half-diameter ranging between the first half-diameter r1 and the second half-diameter r2, and the maximum diameter of the microlenses ML may increase as they approach the second pixel PX2 rather than the first pixel PX1. However, one or more embodiments are not limited thereto, and the horizontal cross-sectional widths of the microlenses ML respectively corresponding to the pixels PX may gradually increase away from the center cp in a specific area unit. The configuration in which the horizontal cross-sectional widths of the microlenses ML vary in area units is described below with reference to FIG. 13.

In the image sensor according to an embodiment, as a microlens ML corresponds to a pixel that is farther from the center cp, the horizontal cross-sectional width of the microlens ML may increase, and even if a pixel PX is distant from the center cp, the focal length of light entering through a microlens ML corresponding that pixel PX may increase. Accordingly, the light may be concentrated at the center of the surfaces of the first photodiode LPD and the second photodiode RPD of the pixel PX, leading to the improvements in the AF separation ratio and the AF function.

FIG. 5B is a cross-sectional view of the image sensor of FIG. 5A, taken along a line I-I′. The descriptions that are the same as those provided above with reference to FIG. 5A are omitted.

FIG. 5B is a cross-sectional view illustrating that the color filter arrays CF, the first microlens ML1, the second microlens ML2, and the third microlens ML3 are arranged above the first pixel PX1, the second pixel PX2, and the third pixel PX3, respectively.

In an embodiment, in the direction from the pixel towards the microlens, the heights of the apexes of the microlenses ML respectively corresponding to the pixels PX may be identical. For example, the direction from the pixel to the microlens may be the third direction. The third direction may be perpendicular to the first direction. For example, the first direction may be the X-axis direction, and the third direction may be the Z-axis direction. The apex of the microlens ML may refer to a point at which the height of the microlens ML in the Z-axis direction is the greatest.

The height of the apex hp1 of the first microlens ML1 may be the first height h1. The height of the apex hp2 of the second microlens ML2 may be the second height h2. The height of the apex hp3 of the third microlens ML3 may be the third height h3. The first height h1, the second height h2, and the third height h3 may be identical.

In an embodiment, the shapes of the microlenses ML may be symmetrical with respect to the centers of the pixels PX respectively corresponding to the microlenses ML. The shape of the first microlens ML1 may be symmetrical with respect to the center pc1 of the first pixel PX1. The shape of the second microlens ML2 may be symmetrical with respect to the center pc2 of the second pixel PX2. The shape of the third microlens ML3 may be symmetrical with respect to the center pc3 of the third pixel PX3.

FIG. 5C is a diagram illustrating pixels including photodiodes, according to an embodiment. Compared to FIG. 5A, the pixels PX of FIG. 5C may each include four photodiodes. The descriptions that are the same as those provided above are omitted.

Referring to FIG. 5C, a pixel array 110 may include a first pixel PX1, a second pixel PX2, and a third pixel PX3. Each of the first pixel PX1, the second pixel PX2, and the third pixel PX3 may include four photodiodes PD. For example, each pixel may include photodiodes PD1 to PD4. In the pixel PX, the photodiode PD1 may be adjacent to the photodiode PD2 in the X-axis direction, the photodiode PD1 may be adjacent to the photodiode PD3 in the Y-axis direction, and the photodiode PD3 may be adjacent to the photodiode PD4 in the X-axis direction. The Y-axis direction may also be referred to herein as the second direction. The second direction may be perpendicular to the first direction.

As the distance from the center cp of the pixel array 110 to the pixel PX increases, the horizontal cross-sectional width of the microlens ML corresponding to the pixel PX may increase. In other words, the farther the microlens ML is from the center cp, the greater the horizontal cross-sectional width of the microlens ML may become. For example, the horizontal cross-sectional width of the second microlens ML2 may be greater than the horizontal cross-sectional width of the first microlens ML1. The horizontal cross-sectional width of the third microlens ML3 may be greater than the horizontal cross-sectional width of the second microlens ML2. The third pixel PX3 may be relatively far from the center cp, and the horizontal cross-sectional width of the third microlens ML3 may be relatively great. Accordingly, light may be focused at the centers of the surfaces of the photodiode PD1 to the photodiode PD4, leading to the improvements in the AF separation ratio and the AF function.

The pixel PX may include four photodiodes and perform the AF function in the first direction (e.g., the x direction) and the second direction (e.g., the y-axis direction). Because the horizontal cross-sectional width of the microlens ML corresponding to the pixel PX increases with the distance from the center cp of the pixel array 110 to the pixel PX, the AF function in the first direction and the second direction may be enhanced.

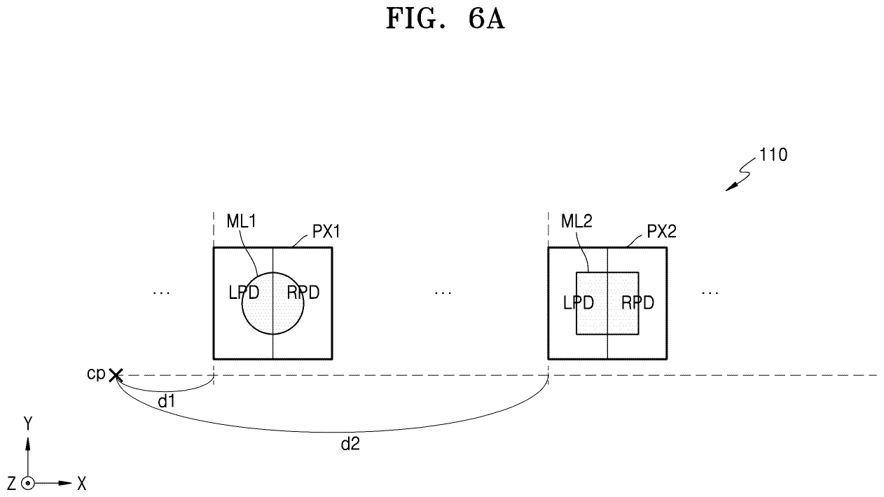

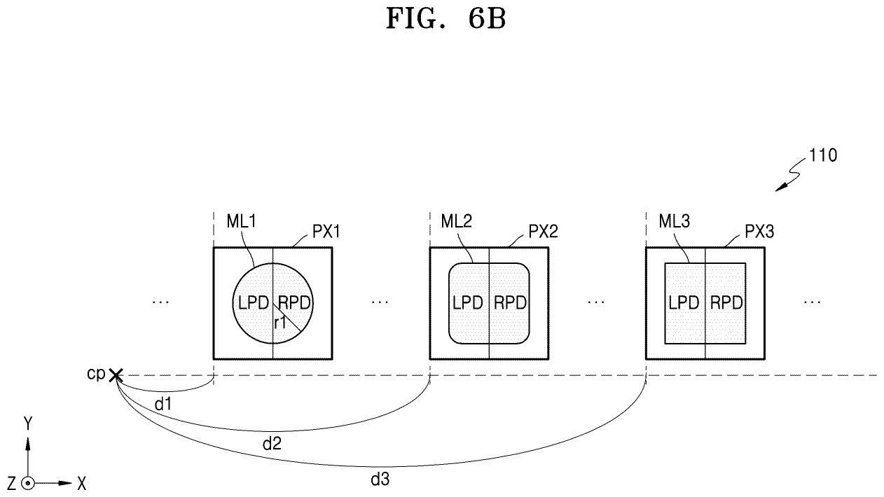

FIG. 6A illustrates that cross-sectional shapes of microlenses are different, according to an embodiment. The descriptions that are the same as those provided above are omitted.

Referring to FIG. 6A, a first microlens ML1 may be arranged above a first pixel PX1. A second microlens ML2 may be arranged above a second pixel PX2. As the microlens ML corresponds to the pixel that is farther from the center cp of the pixel array 110, the horizontal cross-sectional width of the microlens ML may increase. For example, the horizontal cross-sectional width of the second microlens ML2 may be greater than the horizontal cross-sectional width of the first microlens ML1.

In an embodiment, the microlenses ML respectively corresponding to the pixels PX may have different shapes. The shape of the microlens ML corresponding to the pixel PX may vary depending on the distance from the center cp of the pixel array 110 to the pixel PX, and the farther the pixel PX is from the center cp of the pixel array 110, the greater the horizontal cross-sectional width of the microlens ML corresponding to that pixel PX may become. For example, the horizontal cross-section of the first microlens ML1 may have a circular shape, and the horizontal cross-section of the second microlens ML2 may have a quadrangular shape. For example, the cross-sectional shape of the first microlens ML1 contacting the color filter may be a circle, and the cross-sectional shape of the second microlens ML2 contacting the color filter may be a quadrangle. Also, the mask layout used to form the first microlens ML1 may have a circular shape, and the mask layout used to form the second microlens ML2 may have a quadrangular shape. When the mask layout has a quadrangular shape, edge portions of the microlens ML may be rounded because of the condensation of lens materials during the formation of the microlens ML. However, one or more embodiments are not limited thereto. FIG. 6A illustrates that the horizontal cross-section of the first microlens ML1 is circular and that of the second microlens ML2 is quadrangular, but this is only an example. The horizontal cross-sectional shape of the first microlens ML1 may be different from the horizontal cross-sectional of the second microlens ML2. The horizontal cross-sectional width of the second microlens ML2 may greater than the horizontal cross-sectional width of the first microlens ML1.

FIG. 6B illustrates structures of microlenses with different curvatures, according to an embodiment. The descriptions that are the same as those provided above are omitted.

Referring to FIG. 6B, a pixel array 110 may include a first pixel PX1, a second pixel PX2, and a third pixel PX3. A first microlens ML1 may be arranged above the first pixel PX1. A second microlens ML2 may be arranged above the second pixel PX2. A third microlens ML3 may be arranged above the third pixel PX3.

As the microlens ML corresponds to the pixel that is farther from the center cp of the pixel array 110, the horizontal cross-sectional width of the microlens ML may increase. For example, the horizontal cross-sectional width of the third microlens ML3 may be greater than the horizontal cross-sectional width of the second microlens ML2. The horizontal cross-sectional width of the second microlens ML2 may be greater than the horizontal cross-sectional width of the first microlens ML1.

In an embodiment, the microlenses ML respectively corresponding to the pixels PX may have different shapes, and as the distance from the center cp of the pixel array 110 to the pixel PX increases, the curvature of the edges of the microlens ML corresponding to the pixel PX may decrease.

The microlenses ML respectively corresponding to the pixels PX may have different shapes. For example, the horizontal cross-sectional shape of the first microlens ML1 may be a circle. The horizontal cross-sectional shape of the second microlens ML2 may be a quadrangle with rounded edges. The horizontal cross-sectional shape of the third microlens ML3 may be a quadrangle.

As the microlens ML corresponds to the pixel that is farther from the center cp of the pixel array, the curvature of the edges of the microlens ML may decrease. Because the horizontal cross-section of the first microlens ML1 has a circular shape, the curvature of the edges of the second microlens ML2 may be less than the curvature of the edges of the first microlens ML1. Because the horizontal cross-section of the second microlens ML2 has a quadrangular shape with rounded edges, the curvature of the edges of the third microlens ML3 may be less than the curvature of the edges of the edges of the second microlens ML2. FIG. 6B illustrates that the pixel PX includes two photodiodes LPD and RPD. However, the structure of the microlens ML of FIG. 6B may be applied to a pixel including four photodiodes as illustrated in FIG. 5C and may also be applied to a pixel including different numbers of photodiodes.

As the microlens ML corresponds to the pixel that is farther from the center cp of the pixel array, the curvature of the edges of the microlens ML may decrease, and thus, the horizontal cross-sectional width of the microlens ML may increase. Accordingly, even for pixels that are distant from the center cp, the AF separation ratio may increase, and thus, the AF function may be improved.

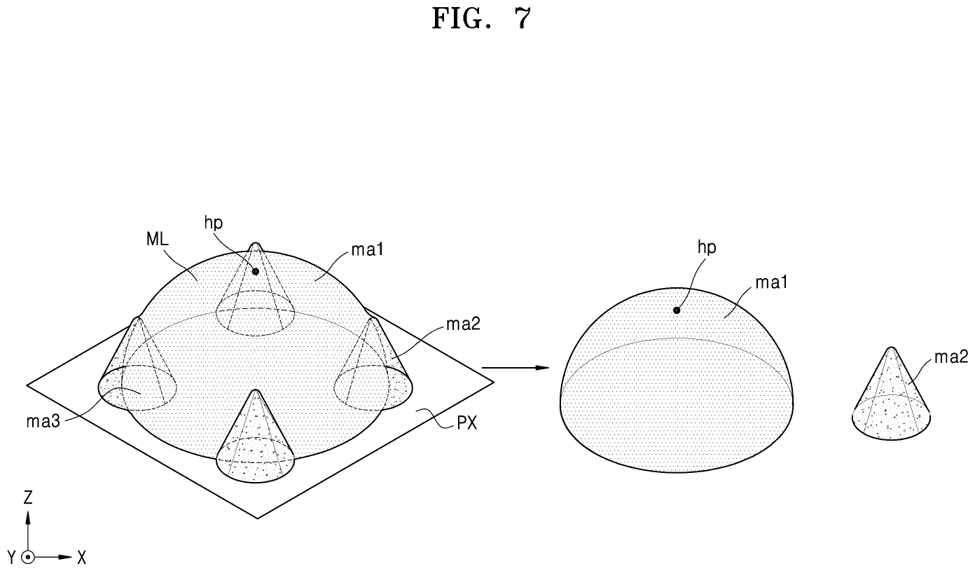

FIG. 7 illustrates a shape of a microlens according to an embodiment. The descriptions that are the same as those provided above are omitted.

Referring to FIG. 7, a microlens ML may be arranged above a pixel PX in the Z-axis direction. The microlens ML may include a first lens area ma1 and a second lens area ma2. The first lens area ma1 and the second lens area ma2 may overlap each other at a specific portion. For example, the first lens area ma1 may overlap the second lens area ma2 in an area ma3. The shape of the microlens ML may be symmetrical with respect to the center of the pixel PX.

In the direction from the pixel PX to the microlens ML, the first lens area ma1 may be an area including the apex hp of the microlens ML. For example, the first lens area ma1 may be an area including the apex hp of the microlens ML in the third direction (e.g., the Z-axis direction) perpendicular to the first direction (e.g., the X-axis direction). The second lens area ma2 may be an area protruding more than the first lens area ma1 in the microlens ML. The second lens area ma2 may include a portion protruding more than the first lens area ma1 in the microlens ML1, and the area ma3 may overlap the first lens area ma1. The second lens area ma2 may protrude from the first lens area ma1 along the horizontal plane formed by the first direction (X-direction) and the second direction (Y-direction).

In an embodiment, as the distance from the center of the pixel array to the pixel PX increases, the horizontal cross-sectional width of the second lens area ma2 of the microlens ML corresponding to the pixel PX may increase. Hereinafter, as the microlens ML corresponds to the pixel that is farther from the center of the pixel array, the horizontal cross-sectional width of the second lens area ma2 increases.

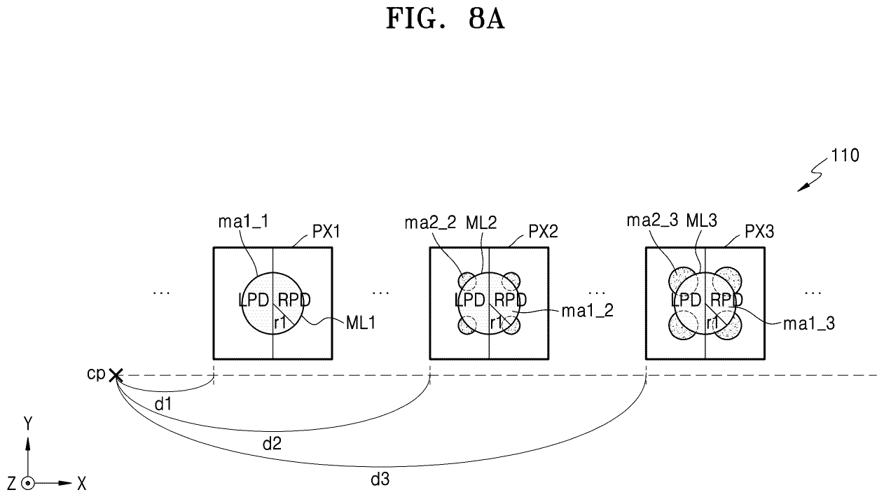

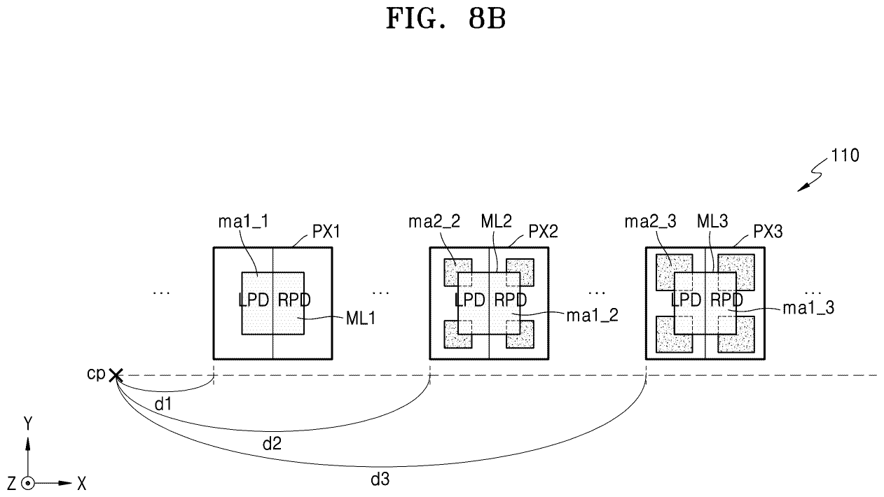

FIG. 8A illustrates microlenses each including a first lens area and a second lens area, according to an embodiment. The descriptions that are the same as those provided above are omitted.

Referring to FIG. 8A, a pixel array 110 may include a first pixel PX1, a second pixel PX2, and a third pixel PX3. The second pixel PX2 may be positioned in the pixel array 110 such that the distance from the center cp of the pixel array 110 to the second pixel PX2 may be greater than that from the center cp to the first pixel PX1. The third pixel PX3 may be positioned in the pixel array 110 such that the distance from the center cp of the pixel array 110 to the third pixel PX3 may be greater than that from the center cp of the pixel array 110 to the second pixel PX2. A first microlens ML1 may be arranged above the first pixel PX1. A second microlens ML2 may be arranged above the second pixel PX2. A third microlens ML3 may be arranged above the third pixel PX3.

The first microlens ML1 may include a first lens area ma1_1. Because the first microlens ML1 does not have a portion protruding more than the first lens area ma1_1, the first microlens ML1 may not include a second lens area. The second microlens ML2 may include a first lens area ma1_2 and a second lens area ma2_2. The second lens area ma2_2 may include a portion protruding more than the first lens area ma1_2. The third microlens ML3 may include a first lens area ma1_3 and a second lens area ma2_3. The second lens area ma2_3 may include a portion protruding more than the first lens area ma1_3. FIG. 8A illustrates that the second microlens ML2 includes four second lens areas ma2_2 and the third microlens ML3 includes four second lens areas ma2_3, but one or more embodiments are not limited thereto.

In an embodiment, as the distance from the center cp of the pixel array 110 to the pixel PX increases, the horizontal cross-sectional width of the second lens area ma2 of the microlens ML corresponding to the pixel PX may increase. For example, the horizontal cross-sectional widths of the first lens area ma1_1 of the first microlens ML1, the first lens area ma1_2 of the second microlens ML2, and the first lens area ma1_3 of the third microlens ML3 may be identical. The lengths of the half-diameters of the horizontal cross-sections of the first lens area ma1_1, the first lens area ma1_2, and the first lens area ma1_3 may be identical.

As the microlens ML corresponds to the pixel PX that is farther from the center cp of the pixel array 110, the horizontal cross-sectional width of the second lens area ma2 may increase to increase the horizontal cross-sectional width of the microlens ML. For example, the first microlens ML1 may not include a second lens area, and the horizontal cross-sectional width of the second lens area ma2_3 of the third microlens ML3 may be greater than the horizontal cross-sectional width of the second lens area ma2_2 of the second microlens ML2. However, one or more embodiments are not limited thereto, and the horizontal cross-sectional widths of the first lens area ma1_3 and the second lens area ma2_3 of the third microlens ML3 may be greater than the horizontal cross-sectional widths of the first microlens area ma1_2 and the second lens area ma2_2 of the second microlens ML2.

In an embodiment, in the microlens ML corresponding to the pixel PX, the horizontal cross-sectional shape of the second lens area ma2 may be the same as the horizontal cross-sectional shape of the first lens area ma1. For example, the second lens area ma2_2 of the second microlens ML2 may partially overlap the first lens area ma1_2 thereof, and the horizontal cross-section of the second lens area ma2_2 may have a circular shape. The horizontal cross-section of the first lens area ma1_2 of the second microlens ML2 may have a circular shape. Also, the second lens area ma2_3 of the third microlens ML3 may partially overlap the first lens area ma1_3 thereof, and the horizontal cross-section of the second lens area ma2_3 may have a circular shape. The horizontal cross-section of the first lens area ma1_3 of the third microlens ML3 may have a circular shape. For example, the horizontal cross-sectional shape of the second lens area ma2_3 may be a circle with a greater radius than that of the second lens area ma2_2.

FIG. 8B illustrates microlenses each including a first lens area and a second lens area, according to an embodiment. The cross-sectional shape of the second lens area ma2 of FIG. 8B may be different from the cross-sectional shape of the second lens area ma2 of FIG. 8A. The descriptions that are the same as those provided above are omitted.

In an embodiment, in the microlens ML corresponding to the pixel PX, the horizontal cross-section of the second lens area ma2 may have the same shape as the horizontal cross-section of the first lens area ma1. The horizontal cross-sections of the second lens area ma2 and the first lens area ma1 may each have a quadrangular shape. For example, the horizontal cross-sections of the second lens area ma2 and the first lens area ma1 may each have a square shape. However, one or more embodiments are not limited thereto. The horizontal cross-sectional shapes of the second lens area ma2 and the first lens area ma1 may vary.

For example, the second lens area ma2_2 of the second microlens ML2 may partially overlap the first lens area ma1_2 thereof, and the horizontal cross-section of the second lens area ma2_2 may have a square shape. For example, the horizontal cross-section of the first lens area ma1_2 of the second microlens ML2 may have a square shape. Also, the second lens area ma2_3 of the third microlens ML3 may partially overlap the first lens area ma1_3 thereof, and the horizontal cross-section of the second lens area ma2_3 may have a square shape. The horizontal cross-section of the first lens area ma1_3 of the third microlens ML3 may have a square shape. For example, the horizontal cross-sectional shape of the second lens area ma2_3 may be a square, each side of which is greater than the sides of the second lens area ma2_2.

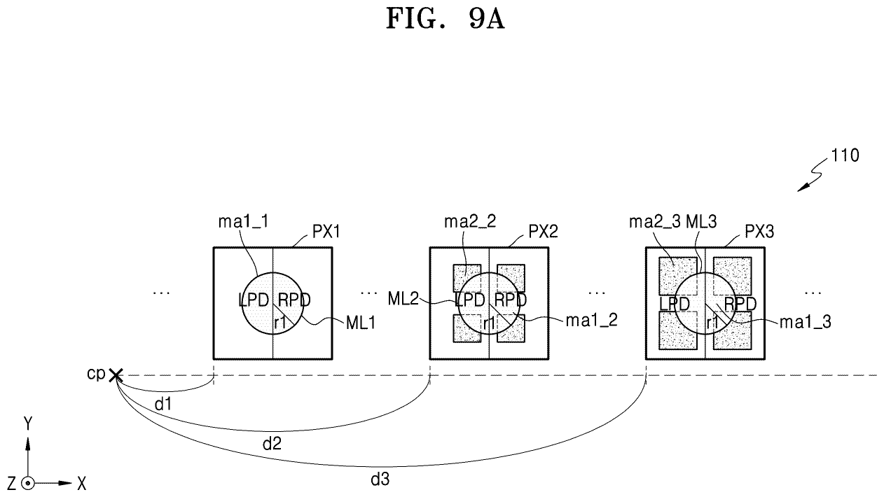

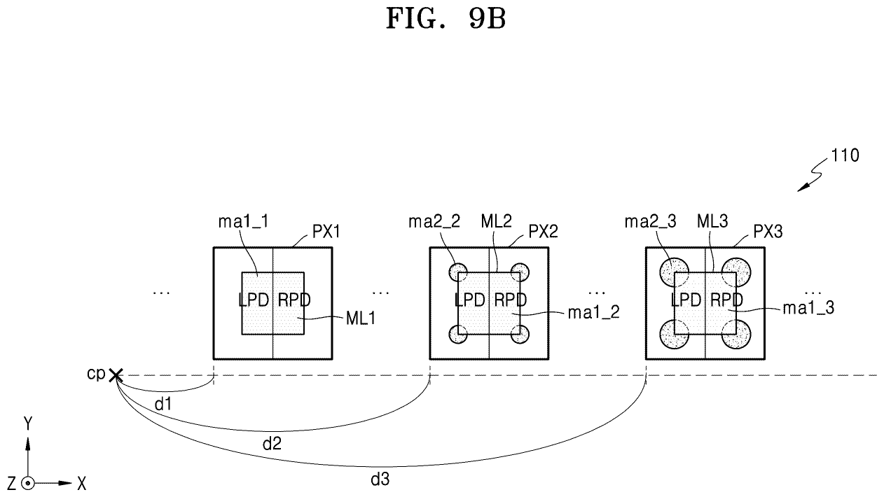

FIG. 9A illustrates a structure in which cross-sectional shapes of a first lens area and a second lens area of a microlens are different, according to an embodiment. The descriptions that are the same as those provided above with reference to FIGS. 8A and 8B are omitted.

In an embodiment, in the microlens ML corresponding to the pixel PX, the horizontal cross-sectional shape of the second lens area ma2 may be different from the horizontal cross-sectional shape of the first lens area ma1. The horizontal cross-section of the second lens area ma2 may have a quadrangular shape, and the horizontal cross-section of the first lens area ma1 may have a circular shape. For example, the horizontal cross-section of the second lens area ma2 may have a square shape, and the horizontal cross-section of the first lens area ma1 may have a circular shape. However, one or more embodiments are not limited thereto. The horizontal cross-sectional shapes of the second lens area ma2 and the first lens area ma1 may vary.

For example, the second lens area ma2_2 of the second microlens ML2 may partially overlap the first lens area ma1_2 thereof, and the horizontal cross-section of the second lens area ma2_2 may have a square shape. The horizontal cross-section of the first lens area ma1_2 of the second microlens ML2 may have a circular shape. Also, the second lens area ma2_3 of the third microlens ML3 may partially overlap the first lens area ma1_3 thereof, and the horizontal cross-section of the second lens area ma2_3 may have a square shape. The horizontal cross-section of the first lens area ma1_3 of the third microlens ML3 may have a circular shape. The horizontal cross-sectional shape of the second lens area ma2_3 may be a square, each side of which is greater than the sides of the second lens area ma2_2. Therefore, the horizontal cross-sectional width of the third microlens ML3 may be greater than the horizontal cross-sectional width of the second microlens ML2.

FIG. 9B illustrates a structure in which cross-sectional shapes of a first lens area and a second lens area of a microlens are different, according to an embodiment. The cross-sectional shape of the second lens area ma2 of FIG. 9B may be different from the cross-sectional shape of the second lens area ma2 of FIG. 9A. The descriptions that are the same as those provided above are omitted.

Referring to FIG. 9B, the horizontal cross-section of the second lens area ma2 may have a circular shape, and the horizontal cross-section of the first lens area ma1 may have a quadrangular shape. For example, the horizontal cross-section of the first lens area ma1 may have a square shape, and the horizontal cross-section of the second lens area ma2 may have a circular shape. However, one or more embodiments are not limited thereto.

For example, the second lens area ma2_2 of the second microlens ML2 may partially overlap the first lens area ma1_2 thereof, and the horizontal cross-section of the second lens area ma2_2 may have a circular shape. The horizontal cross-section of the first lens area ma1_2 of the second microlens ML2 may have a square shape. Also, the second lens area ma2_3 of the third microlens ML3 may partially overlap the first lens area ma1_3 thereof, and the horizontal cross-section of the second lens area ma2_3 may have a circular shape. The horizontal cross-section of the first lens area ma1_3 of the third microlens ML3 may have a square shape. The horizontal cross-sectional shape of the second lens area ma2_3 may be a circle with a radius greater than that of the second lens area ma2_2. The horizontal cross-sectional width of the third microlens ML3 may be greater than the horizontal cross-sectional width of the second microlens ML2, and the AF function may be improved.

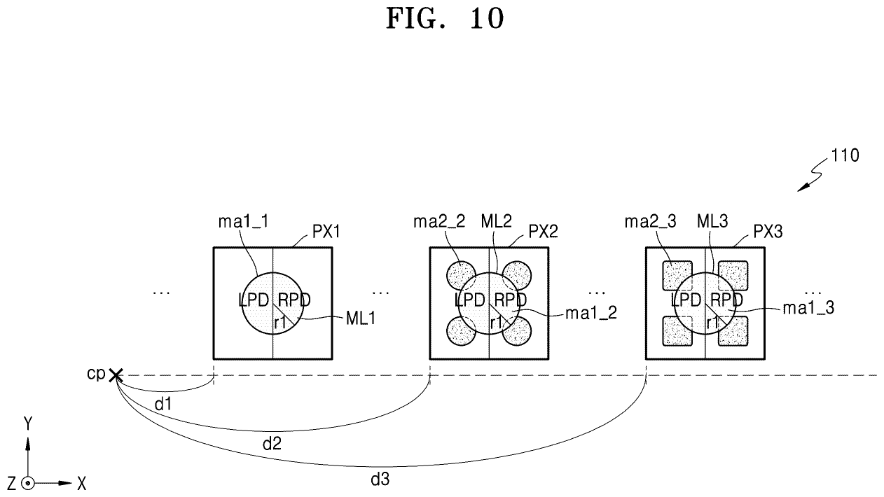

FIG. 10 illustrates a structure in which a cross-sectional shape of a second lens area varies depending on the distance from a center of a pixel array, according to an embodiment. The descriptions that are the same as those provided above are omitted.

In an embodiment, in the microlens ML corresponding to the pixel PX, the horizontal cross-sectionals shape of the second lens area ma2 may vary depending on the distance from the center cp of the pixel array 110 to the microlens ML. For example, the first microlens ML1 may not include a second lens area. The second microlens ML2 may include a second lens area ma2_2, and the horizontal cross-sectional shape of the second lens area ma2_2 may be a circle. The horizontal cross-sectional width of the second microlens ML2 may be greater than the horizontal cross-sectional width of the first microlens ML1. The third microlens ML3 may include a second lens area ma2_3, and the horizontal cross-sectional shape of the second lens area ma2_3 may be a quadrangle with rounded edges.

In an embodiment, as the distance from the center cp of the pixel array 110 to the pixel PX increases, the curvature of the second lens area ma2 of the microlens ML corresponding to the pixel PX may decrease. For example, the horizontal cross-section of the second lens area ma2_2 may have a circular shape. The horizontal cross-sections of the second lens area ma2_2 and the first lens area ma1_2 may each have a circular shape. In addition, the horizontal cross-section of the second lens area ma2_3 of the third microlens ML3 may have a quadrangular shape with rounded edges. The horizontal cross-sectional shape of the second lens area ma2_2 may be different from the horizontal cross-sectional shape of the first lens area ma1_2. Because the horizontal cross-sectional shape of the second lens area ma2_3 is a quadrangle with rounded edges, the second lens area ma2_3 may have a curvature that is less than that of the second lens area ma2_2 having the circular horizontal cross-section and may have a greater horizontal cross-sectional width than the second lens area ma2_2.

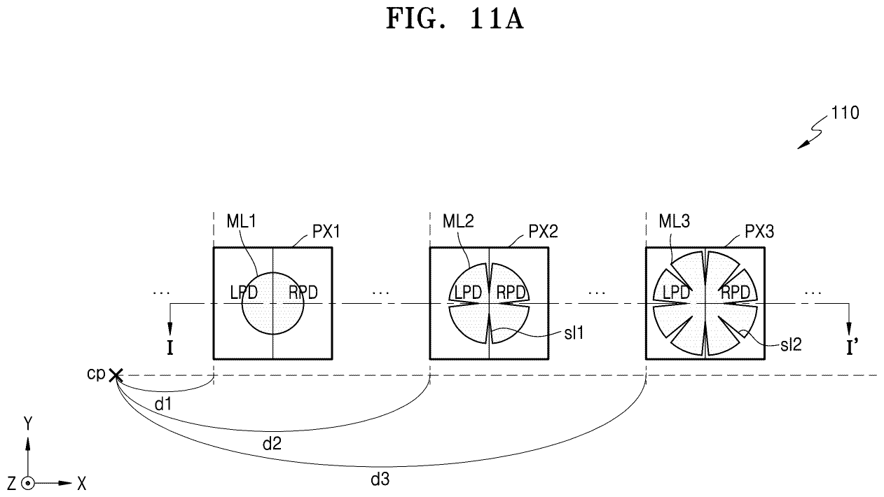

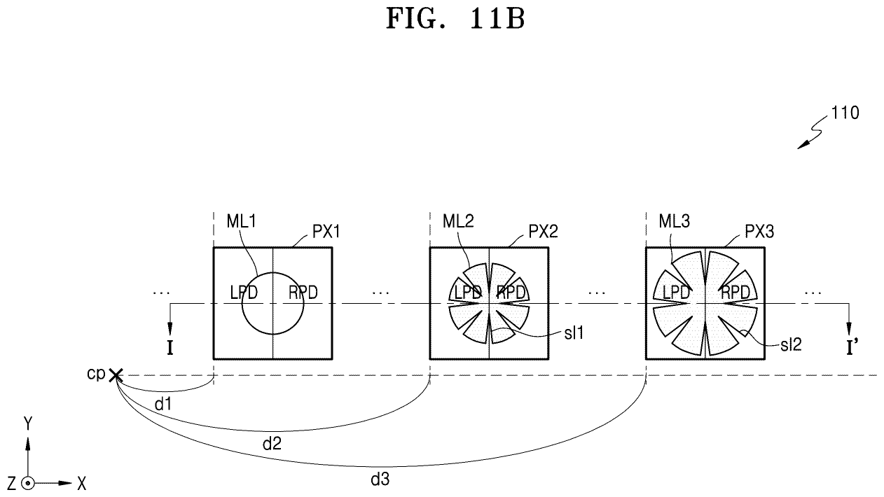

FIG. 11A illustrates slits of a microlens according to an embodiment. Referring to FIG. 11A, a microlens ML corresponding to a pixel that is distant from the center cp of a pixel array 110 may include a greater number of slits sl. The descriptions that are the same as those provided above are omitted.

Referring to FIG. 11A, the pixel array 110 may include a first pixel PX1, a second pixel PX2, and a third pixel PX3. A first microlens ML1 may be arranged above the first pixel PX1. A second microlens ML2 may be arranged above the second pixel PX2. A third microlens ML3 may be arranged above the third pixel PX3.

As the microlens ML corresponds to the pixel that is farther from the center cp of the pixel array, the horizontal cross-sectional width of the microlens ML may increase. For example, the horizontal cross-sectional width of the third microlens ML3 may be greater than the horizontal cross-sectional width of the second microlens ML2. The horizontal cross-sectional width of the second microlens ML2 may be greater than the horizontal cross-sectional width of the first microlens ML1.

The microlens ML may include the slits sl. The slit may refer to a crack where a portion of the microlens ML is spaced apart from another portion thereof or a crack spaced apart from a mask layout used to form the microlens ML.

In an embodiment, as the distance from the center cp of the pixel array 110 to the pixel PX increases, the number of slits sl included in the horizontal cross-sectional shape of the microlens ML corresponding to the pixel PX may increase. For example, the horizontal cross-sectional shape of the third microlens ML3 may include more slits sl than the horizontal cross-sectional shape of the second microlens ML2. The horizontal cross-sectional shape of the second microlens ML2 may include more slits sl than the horizontal cross-sectional shape of the first microlens ML1.

For example, the horizontal cross-sectional shape of the first microlens ML1 may not include slits sl. The horizontal cross-sectional shape of the second microlens ML2 may include first slits sl1. The horizontal cross-sectional shape of the second microlens ML2 may include four first slits sl1. The horizontal cross-sectional shape of the third microlens ML3 may include second slits sl2. The horizontal cross-sectional shape of the third microlens ML3 may include eight second slits sl2. However, one or more embodiments are not limited thereto, and the number of slits sl may vary. FIG. 11A illustrates that the pixel PX includes two photodiodes LPD and RPD. However, the structure of the microlens ML of FIG. 11A may be applied to the pixel including four photodiodes as illustrated in FIG. 5C and may also be applied to the pixel including different numbers of photodiodes.

As the microlens ML corresponds to the pixel that is farther from the center cp of the pixel array 110, the horizontal cross-sectional shape of the microlens ML may include a greater number of slits sl, and thus, even if the horizontal cross-sectional width of the microlens ML increases, the height of the apex of the microlens may decrease relative to the horizontal cross-sectional width of the microlens ML. Accordingly, even for pixels that are distant from the center cp, the AF separation ratio may increase, and thus, the AF function may be improved.

FIG. 11B illustrates slits of a microlens according to an embodiment. Referring to FIG. 11B, as the microlens ML corresponds to the pixel that is farther from the center cp of the pixel array, the slits sl may increase in size. The descriptions that are the same as those provided above with reference to FIG. 11A are omitted.

Referring to FIG. 11B, as the microlens ML corresponds to the pixel that is farther from the center cp of a pixel array 110, the horizontal cross-sectional width of the microlens ML may increase. In an embodiment, as the distance from the center cp of the pixel array 110 to the pixel PX increases, the size of slits sl included in the horizontal cross-sectional shape of the microlens ML corresponding to the pixel PX may increase. For example, the horizontal cross-sectional shape of the third microlens ML3 may include slits sl with greater sizes than those included in the horizontal cross-sectional shape of the second microlens ML2. The horizontal cross-sectional shape of the second microlens ML2 may include the slits sl with greater sizes than those included in the horizontal cross-sectional shape of the first microlens ML1.

For example, the horizontal cross-sectional shape of the first microlens ML1 may not include slits sl. The horizontal cross-sectional shape of the second microlens ML2 may include first slits sl1. The horizontal cross-sectional shape of the second microlens ML2 may include eight first slits sl1. The horizontal cross-sectional shape of the third microlens ML3 may include second slits sl2. The horizontal cross-sectional shape of the third microlens ML3 may include eight second slits sl2. The size of the second slit sl2 may be greater than the size of the first slit sl1. However, one or more embodiments are not limited thereto.

As the microlens ML corresponds to the pixel that is farther from the center cp of the pixel array 110, the horizontal cross-sectional shape of the microlens ML may include slits sl having a relatively great size, and thus, even if the horizontal cross-sectional width of the microlens ML increases, the height of the apex of the microlens ML may decrease relative to the horizontal cross-sectional width of the microlens ML. Accordingly, even for pixels that are distant from the center cp, the AF separation ratio may increase, and thus, the AF function may be improved.

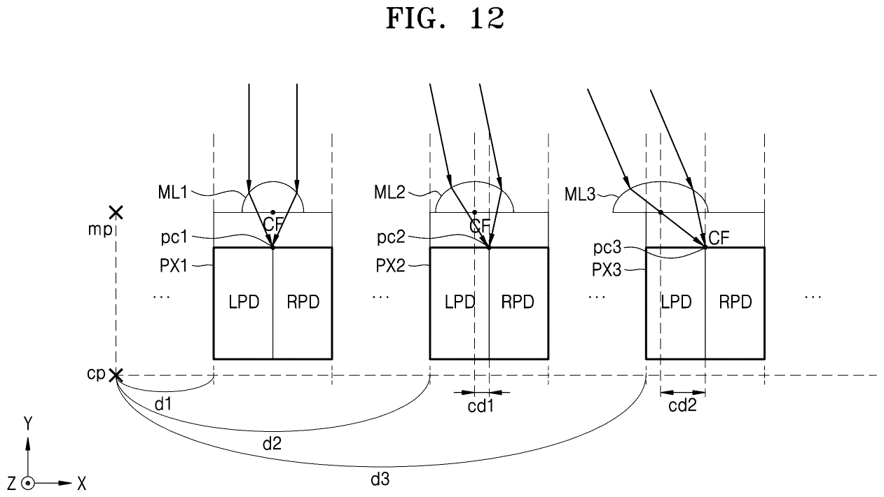

FIG. 12 illustrates a structure in which the microlenses of FIG. 5A are shifted. FIG. 12 is a cross-sectional view of the image sensor of FIG. 5A, taken along a line I-I′. The descriptions that are the same as those provided above with reference to FIGS. 5A and 5B are omitted.

FIG. 12 is a cross-sectional view illustrating that color filter arrays CF, a first microlens ML1, a second microlens ML2, and a third microlens ML3 are arranged above the first pixel PX1, the second pixel PX2, and the third pixel PX3, respectively. For example, the horizontal cross-sectional width of the second microlens ML2 may be greater than the horizontal cross-sectional width of the first microlens ML1. The horizontal cross-sectional width of the third microlens ML3 may be greater than the horizontal cross-sectional width of the second microlens ML2.

At least one of the microlenses ML may be shifted towards a center mp of the microlens array, based on the distance from the center cp of the pixel array to the pixel PX corresponding to the microlens ML. The center mp of the microlens array may be the midpoint of the microlens array and correspond to the center cp of the pixel array. For example, because the first pixel PX1 is away from the center cp by a first distance d1 and is relatively close to the center cp, the first microlens ML1 may not be shifted.

For example, because the second pixel PX2 is away from the center cp by the second distance d2 and is farther from the center cp than the first pixel PX1, the second microlens ML2 may be shifted towards the center mp. With respect to a center pc2 of the second pixel PX2, the second microlens ML2 may be shifted towards the center mp of the microlens array by a first central length cd1.

For example, because the third pixel PX3 is away from the center cp by the third distance d3 and is farther from the center cp than the first pixel PX1, the third microlens ML3 may be shifted towards the center mp. With respect to a center pc3 of the third pixel PX3, the third microlens ML3 may be shifted towards the center mp of the microlens array by a second central length cd2.

In an embodiment, as the distance from the center mp to the microlens ML increases, the microlens ML may be shifted further towards the center mp. For example, the second central length cd2 may be greater than the first central length cd1. The third microlens ML3 may be shifted further towards the center mp, compared to the second microlens ML2 that is shifted towards the center mp. As the microlens ML is shifted towards the center mp, light may be incident to the pixel PX on an edge portion of the pixel array. Light, of which the amount is equal or similar to that of the light incident to the pixel PX that is relatively close to the center cp, may also be incident to the pixel PX on the edge portion of the pixel array, and the field curvature may be compensated for. In addition, because microlenses ML with great horizontal cross-sectional widths are arranged as the distance from the center mp increases, the AF performance may be improved.

FIG. 12 illustrates that the microlenses ML respectively corresponding to the pixels PX have the same shape, but one or more embodiments are not limited thereto. The description may also be applied to the above-described shapes of the microlenses ML. For example, for the microlenses of FIGS. 1 to 10, 11A, and 11B, based on the distance from the center cp of the pixel array to pixels PX corresponding to the microlenses ML, the microlenses ML may be shifted towards the center mp of the microlens array. For example, as illustrated in FIG. 8A, the third microlens ML3 may be shifted further than the second microlens ML2 in the x-axis direction. The second microlens ML2 may be shifted further than the first microlens ML1 in the x-axis direction.

FIG. 13 illustrates a microlens array according to an embodiment. FIG. 13 illustrates horizontal cross-sections of pixels PX and microlenses ML respectively corresponding to the pixels PX. The descriptions that are the same as those provided above are omitted.

Referring to FIG. 13, a pixel array 110 may include the pixels PX, and each pixel PX may include two or more photoelectric transformation elements. A microlens array may be arranged above the pixel array 110 and include the microlenses ML respectively corresponding to the pixels PX.

The microlens array may include a first area ar1 and a second area ar2. The first area ar1 may include first microlenses ML1′. The second area ar2 may include second microlenses ML2′. The first area ar1 may be an area of the microlens array that is closer to the center mp of the microlens array than the second area ar2. The distance from the center mp of the microlens array to each of the first microlenses ML1′ included in the first area ar1 may be less than the distance from the center mp of the microlens array to each of the second microlenses ML2′ included in the second area ar2. FIG. 13 illustrates that the first area ar1 includes 16 first microlenses ML1′ and the second area ar2 includes 48 second microlenses ML2′; however, it is only an example, and one or more embodiments are not limited thereto. The first area ar1 and the second area ar2 may be set based on the distance from the center mp of the microlens array to the microlens ML.

The microlens ML included in the first area ar1 may be the first microlens ML1′, and the microlens ML2 included in the second area ar2 may be the second microlens ML2′. The microlenses ML within the same area of the microlens array may be identical. For example, the first microlenses ML1′ in the first area ar1 may be identical, the second microlenses ML2′ in the second area ar2 may be identical, and the first microlenses ML1′ may be different from the second microlenses ML2′.

The microlenses ML included in the same area in the microlens array may have the same cross-sectional width. The microlenses ML within the same area of the microlens array may have identical horizontal cross-sectional widths. The horizontal cross-sectional widths of the microlenses ML may be different by area unit, according to the distance from the center mp of the microlens array.

The horizontal cross-sectional width of the second microlens ML2′ may be greater than the horizontal cross-sectional width of the first microlens ML1′. That is, the horizontal cross-sectional width of the microlens ML included in the area of the microlens array that is far from the center mp may be great. The distance to the second microlens ML2′ in the second area ar2 may be greater than the distance to the first microlens ML1′ in the first area ar1, and the horizontal cross-sectional width of the second microlens ML2′ may be relatively greater than the horizontal cross-sectional width of the first microlens ML1′.

In an embodiment, the cross-sectional shape of the first microlens ML1′ may be the same as that of the second microlens ML2′, and the maximum diameter of the cross-section of the second microlens ML2′ may be greater than the maximum diameter of the cross-section of the first microlens ML1′. For example, the horizontal cross-sectional shapes of the first microlens ML1′ and the second microlens ML2′ may each be a circle. However, one or more embodiments are not limited thereto. The horizontal cross-sectional shapes of the first microlens ML1′ and the second microlens ML2′ may vary; for example, the shapes may be quadrangles or quadrangles with rounded edges.

In an embodiment, the cross-sectional shape of the first microlens ML1′ may be different from the cross-sectional shape of the second microlens ML2′, and the curvature of the edges of the second microlens ML2′ may be less than that of the edges of the first microlens ML1′. For example, the cross-sectional shape of the first microlens ML1′ may be a circle, and the cross-sectional shape of the second microlens ML2′ may be a quadrangle with rounded edges. Because the cross-sectional shape of the first microlens ML1′ is a circle, the curvature of the edges of the second microlens ML2′ may be less than the curvature of the edges of the first microlens ML1′.

As described above with reference to FIG. 7, the first microlens ML1′ and the second microlens ML2′ may each include a first lens area and a second lens area. The first lens area may include an apex of the microlens ML, and the second lens area may include a portion that protrudes more than the first lens area in the microlens ML. The cross-sectional width of the second lens area of the second microlens ML2′ may be greater than the cross-sectional width of the first lens area of the first microlens ML1′. For example, the cross-section of the second lens area of the second microlens ML2′ may be a greater circle than the cross-section of the second lens area of the first microlens ML1′.

In an embodiment, the first lens area and the second lens area included in each of the first microlens ML1′ and the second microlens ML2′ may have the same cross-sectional shape. For example, the first lens area and the second lens area included in each of the first microlens ML1′ and the second microlens ML2′ may have the same cross-sectional shape, specifically, a circular shape. For example, the first lens area and the second lens area included in each of the first microlens ML1′ and the second microlens ML2′ may have the same cross-sectional shape, specifically, a quadrangular shape.

In an embodiment, the cross-sectional shape of the second lens area of the second microlens ML2′ may be the same as the cross-sectional shape of the second lens area of the first microlens ML1′. For example, the cross-section of the second lens area of the second microlens ML2′ may be a greater diameter than the cross-section of the second lens area of the first microlens ML1′. For example, the cross-section shape of the second lens area of the second microlens ML2′ may be a greater width than the cross-sectional shape of the first lens area included in the first microlens ML1′.

In an embodiment, the cross-sectional shape of the second lens area included in the second microlens ML2′ may be different from the cross-sectional shape of the second lens area included in the first microlens ML1′, and the curvature of the second lens area included in the second microlens ML2′ may be less than that of the second lens area included in the first microlens ML1′. For example, the cross-sectional shape of the second lens area included in the second microlens ML2′ may be a quadrangle with rounded edges and may be different from the cross-sectional shape of the second lens area included in the first microlens ML1′ that is a circle. Because the cross-sectional shape of the second lens area included in the second microlens ML2′ is a quadrangle with rounded edges, the curvature of the second lens area included in the second microlens ML2′ may be less than that of the second lens area included in the first microlens ML1′. The structure of the microlens ML described with reference to FIGS. 1 to 12 may be applied to that illustrated in FIG. 13.

In the image sensor according to an embodiment, as a microlens corresponds to the pixel that is farther from the center mp, the cross-sectional diameter/width of the microlens ML may increase, and even if the pixel is farther from the center mp, the focal length of light that is incident through the microlens ML corresponding to the pixel may increase. Accordingly, the AF separation ratio may increase and the AF function may be improved.

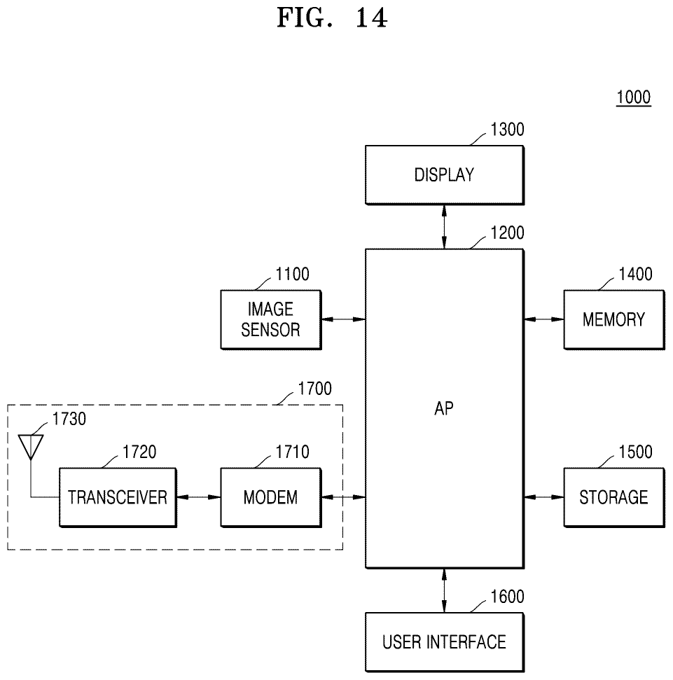

FIG. 14 is a block diagram of an electronic device according to an embodiment. For example, an electronic device 1000 may be a portable terminal.

Referring to FIG. 14, the electronic device 1000 according to an embodiment may include an application processor 1200, an image sensor 1100, a display device 1300, a memory 1400, a storage 1500, a user interface 1600, and a wireless transceiver 1700. The descriptions regarding the image sensor according to embodiments of FIGS. 1 to 13 and the operation method of the image sensor may be applied to the image sensor 1100.

The image sensor 1100 may include a pixel array including a plurality of pixels and a microlens array including a plurality of microlenses respectively corresponding to the pixels. As the microlens corresponds to the pixel that is farther from the center of the pixel array, the horizontal cross-sectional width of the microlens may increase. In an embodiment, the microlenses respectively corresponding to the pixels have the same shape, and as the distance from the center of the pixel array increases, the maximum diameter of the horizontal cross-section of the microlens may increase.

In an embodiment, the cross-sectional shapes of the microlenses are different according to the distance from the center of the pixel array, and as the distance from the center of the pixel array increases, the curvature of the edges of the microlens may decrease.

In an embodiment, at least one of the microlenses may include a first lens area including the apex of the microlens and a second lens area including a portion protruding more than the first lens area, and as the distance from the center of the pixel array increases, the cross-sectional area of the second area may increase. Accordingly, the AF function of the image sensor 1100 may be improved.

The application processor 1200 may control general operations of the electronic device 1000 and may be provided as a system on chip (SoC) for executing application programs, the operation system, and the like.

The application processor 1200 may receive output data from the image sensor 1100.

The image sensor 1100 may generate image data based on a received optical signal and provide the generated image data to the application processor 1200. The image data may be referred to as a pixel value. The image sensor 1100 may generate image data with reduced lens shading.

The memory 1400 may be implemented as a volatile memory, such as dynamic random access memory (DRAM) or static random access memory (SRAM), or as a non-volatile resistive memory, such as ferroelectric random access memory (FeRAM), resistive random access memory (RRAM), or phase-change memory (PRAM). The memory 1400 may store programs and/or data executed or processed by the application processor 1200.

The storage 1500 may be implemented as a non-volatile memory device, such as NAND flash or resistive memory, and for example, the storage 1500 may be provided in the form of memory cards, such as a multimedia card (MMC), an embedded MMC (eMMC), a secure digital (SD) card, or a micro SD card. The storage 1500 may store data and/or programs regarding execution algorithm for controlling image processing operations of the image sensor 1100 and may load the data and/or programs onto the memory 1400 when the image processing operations are performed. In an embodiment, the storage 1500 may store output image data generated by the image sensor 1100, for example, corrected image data or post-processed image data.

The user interface 1600 may be implemented as various devices capable of receiving user inputs, and examples of the devices include a keyboard, a curtain key panel, a touch panel, a fingerprint sensor, and a microphone. The user interface 1600 may receive user inputs and provide signals corresponding to the received user inputs to the application processor 1200.

The wireless transceiver 1700 may include a transceiver 1720, a modem 1710, and an antenna 1730.

While aspects of the inventive concept have been particularly shown and described with reference to embodiments thereof, it will be understood that various changes in form and details may be made therein without departing from the spirit and scope of the following claims.

What is claimed is:

1. An image sensor comprising:
a pixel array comprising a plurality of pixels; and
a microlens array arranged above the pixel array,
wherein each of the plurality of pixels comprises at least two photoelectric transformation elements,
the microlens array comprises a plurality of microlenses respectively corresponding to the plurality of pixels in the pixel array, and
as a distance from a center of the pixel array to the pixels included in the pixel array increases, a horizontal cross-sectional width of a microlens corresponding to the pixels increases.

2. The image sensor of claim 1, wherein the plurality of microlenses have the same shape, and
as the distance from the center of the pixel array to the pixels included in the plurality of pixels increases, a maximum diameter of the horizontal cross-section of the microlens corresponding to the pixels increases.

3. The image sensor of claim 1, wherein the horizontal cross-sectional shape of the microlens corresponding to the pixels included in the plurality of pixels varies with the distance from the center of the pixel array to the pixels.

4. The image sensor of claim 3, wherein as the distance from the center of the pixel array to the pixels included in the plurality of pixels increases, a curvature of edges of the microlens corresponding to the pixels deceases.

5. The image sensor of claim 1, wherein at least one of the plurality of microlenses comprises a first lens area comprising an apex in a direction towards the microlens array from the pixel array and a second lens area comprising a portion protruding from the first lens area, and
as the distance from the center of the pixel array to the pixels included in the plurality of pixels increases, a horizontal cross-sectional width of the second lens area of the microlens corresponding to the pixels increases.

6. The image sensor of claim 5, wherein a horizontal cross-sectional shape of the second lens area is the same as a horizontal cross-sectional shape of the first lens area.

7. The image sensor of claim 5, wherein a horizontal cross-sectional shape of the second lens area is different from a horizontal cross-sectional shape of the first lens area.

8. The image sensor of claim 5, wherein a horizontal cross-sectional shape of the second lens area of the microlens corresponding to the pixels included in the plurality of pixels varies with the distance from the center of the pixel array to the pixels, and
as the distance from the center of the pixel array to the pixels included in the plurality of pixels increases, a curvature of the second lens areas of the microlens corresponding to the pixels decreases.

9. The image sensor of claim 1, wherein at least one of the plurality of microlenses is shifted towards a center of the microlens array based on a distance from the center of the pixel array to a pixel corresponding to the at least one microlens.

10. The image sensor of claim 1, wherein, in a direction from the pixel array to the microlens array, heights of apexes of the plurality of microlenses respectively corresponding to the plurality of pixels are identical.

11. The image sensor of claim 1, wherein a shape of each of the plurality of microlenses is symmetrical with respect to a center of each of the plurality of pixels respectively corresponding to the plurality of microlenses.

12. An image sensor comprising:
a pixel array comprising a plurality of pixels each comprising at least two photoelectric transformation elements; and
a microlens array corresponding to each of the plurality of pixels included in the pixel array,
wherein the microlens array comprises a first area comprising a plurality of first microlenses and a second area comprising a plurality of second microlenses, wherein a distance from a center of the microlens array to the plurality of first microlenses in the first area is less than a distance from the center of the microlens array to the plurality of second microlenses in the second area, and
a cross-sectional width of each second microlens is greater than a cross-sectional width of each first microlens.

13. The image sensor of claim 12, wherein a cross-sectional shape of the first microlens is the same as a cross-sectional shape of the second microlens, and
a maximum diameter of a cross-section of the second microlens is greater than a maximum diameter of a cross-section of the first microlens.

14. The image sensor of claim 12, wherein a cross-sectional shape of the first microlens is different from a cross-sectional shape of the second microlens, and
an edge curvature of the second microlens is less than an edge curvature of the first microlens.

15. The image sensor of claim 12, wherein each of the first microlens and the second microlens comprises a first lens area comprising its apex and a second lens area comprising a portion that protrudes from the first lens area, and
a cross-sectional width of the second lens area of the second microlens is greater than a cross-sectional width of the second lens area of the first microlens.

16. The image sensor of claim 15, wherein the first lens area and the second lens area of each of the first microlens and the second microlens have the same cross-sectional shape.

17. The image sensor of claim 15, wherein a cross-sectional shape of the second lens area of the second microlens is the same as a cross-sectional shape of the second lens area of the first microlens.

18. The image sensor of claim 15, wherein a cross-sectional shape of the second lens area of the second microlens is different from a cross-sectional shape of the second lens area of the first microlens, and
a curvature of the second lens area of the second microlens is less than a curvature of the second lens area of the first microlens.

19. An image sensor comprising:
a pixel array comprising a first pixel and a second pixel; and
a microlens array comprising a first microlens, which corresponds to the first pixel and is arranged above the first pixel, and a second microlens, which corresponds to the second pixel and is arranged above the second pixel,
wherein a distance from a center of the pixel array to the second pixel is greater than a distance from the center of the pixel array to the first pixel,
a horizontal cross-sectional shape of the first microlens is different from a horizontal cross-sectional shape of the second microlens, and
a maximum diagonal length of the horizontal cross-section of the second microlens is greater than a maximum diagonal length of the horizontal cross-section of the first microlens.

20. The image sensor of claim 19, wherein the first microlens is shifted by a first central length in a direction towards a center of the microlens array with respect to a center of the first pixel,
the second microlens is shifted by a second central length in the direction towards the center of the microlens array with respect to a center of the second pixel, and
the second central length is greater than the first central length.
